(19) United States
(12) Patent Application Publication
(10) Pub. No.: US 2026/0198339 A1
(43) Pub. Date: Jul. 9, 2026

(54) ELECTRONIC DEVICE

(71) Applicant: Advanced Semiconductor Engineering, Inc., Kaohsiung (TW)

(72) Inventors: Fan-Yu MIN, Kaohsiung (TW); Meng-Wei HSIEH, Kaohsiung (TW)

(73) Assignee: Advanced Semiconductor Engineering, Inc., Kaohsiung (TW)

(21) Appl. No.: 19/281,536

(22) Filed: Jul. 25, 2025

Related U.S. Application Data
(60) Provisional application No. 63/743,590, filed on Jan. 9, 2025.

(51) Int. Cl. H01L 23/00; H01L 21/56; H01L 23/31; H01L 23/538; H01L 23/60; H01L 25/18; H10B 80/00; H10D 80/30

(52) U.S. Cl. CPC H10W 70/611; H10B 80/00; H10W 74/121; H10W 74/141; H10W 90/401; H10D 80/30; H10W 42/60; H10W 72/334; H10W 74/01; H10W 74/10; H10W 74/15; H10W 90/00; H10W 90/722; H10W 90/724; H10W 90/733; H10W 90/734

(57) ABSTRACT

The present disclosure provides an electronic device. The electronic device includes a redistribution layer (RDL), a component disposed over the RDL, and an underfill disposed between the RDL and the component. The electronic device also includes an encapsulant covering the component. The encapsulant or the underfill defines a surface adjacent to a sidewall of the component and substantially vertical to the component.

### CROSS REFERENCE TO RELATED APPLICATION

This application claims the benefit of U.S. provisional application No. 63/743,590, filed Jan. 9, 2025, the content of which is incorporated herein by reference in its entirety.

### BACKGROUND

### 1. Technical Field

The present disclosure relates to an electronic device.

### 2. Description of the Related Art

A Fan-out Multi-Chip Module (FO-MCM) integrates multiple chips within a single encapsulant, using a redistribution layer (RDL) to fan out I/Os. However, traditional FO-MCMs can incur higher costs and lower yields, as damaged components cannot be removed or replaced once molding is complete.

### SUMMARY

In some arrangements, an electronic device includes a redistribution layer (RDL), a component disposed over the RDL, and an underfill disposed between the RDL and the component. The electronic device also includes an encapsulant covering the component. The encapsulant or the underfill defines a surface adjacent to a sidewall of the component and substantially vertical to the component.

In some arrangements, an electronic device includes an RDL, a chip disposed over the RDL, and a memory package disposed over the RDL and adjacent to the chip. The memory package includes a first encapsulant. The electronic device also includes a second encapsulant covering the memory package. The first encapsulant and the second encapsulant have a first interface therebetween.

In some arrangements, an electronic device includes an RDL, an interposer disposed over the RDL, and an underfill disposed between the RDL and the interposer. The electronic device also includes a first encapsulant covering the underfill. The first encapsulant or the underfill defines an opening over the interposer for accommodating a memory package.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1A illustrates a cross-sectional view of an electronic device in accordance with some arrangements of the present disclosure.

FIG. 1B illustrates a partial enlarged view of an electronic device in accordance with some arrangements of the present disclosure.

FIG. 1C illustrates a partial enlarged view of an electronic device in accordance with some arrangements of the present disclosure.

FIG. 1D illustrates a partial enlarged view of an electronic device in accordance with some arrangements of the present disclosure.

FIG. 2A illustrates a cross-sectional view of an electronic device in accordance with some arrangements of the present disclosure.

FIG. 2B illustrates a partial enlarged view of an electronic device in accordance with some arrangements of the present disclosure.

FIG. 2C illustrates a partial enlarged view of an electronic device in accordance with some arrangements of the present disclosure.

FIG. 2D illustrates a partial enlarged view of an electronic device in accordance with some arrangements of the present disclosure.

FIG. 2E illustrates a cross-sectional view of an electronic device in accordance with some arrangements of the present disclosure.

FIG. 2F illustrates a cross-sectional view of an electronic device in accordance with some arrangements of the present disclosure.

FIG. 2G illustrates a cross-sectional view of an electronic device in accordance with some arrangements of the present disclosure.

FIGS. 3A, 3B, 3C, 3D, 3E, 3F, 3G, 3H, 3I, and 3J are cross-sections of one or more stages of a method of manufacturing an electronic device in accordance with some arrangements of the present disclosure.

FIGS. 4A, 4B, 4C, 4D, and 4E are cross-sections of one or more stages of a method of manufacturing an electronic device in accordance with some arrangements of the present disclosure.

### DETAILED DESCRIPTION

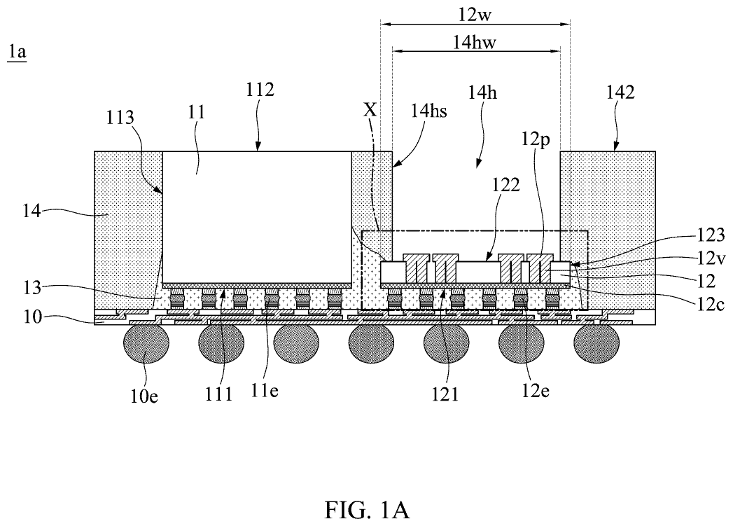

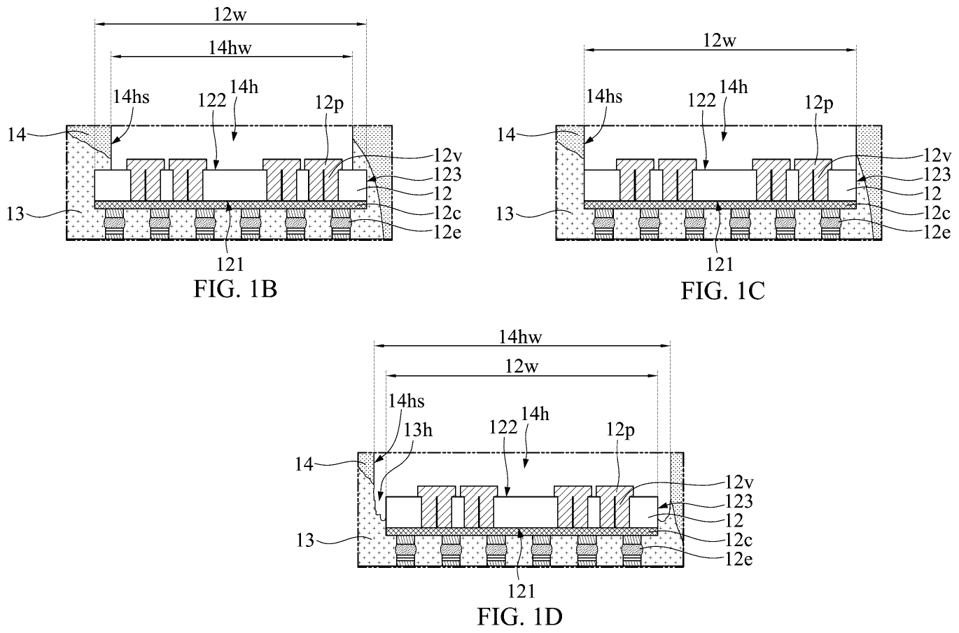

FIG. 1A illustrates a cross-sectional view of an electronic device 1a in accordance with some arrangements of the present disclosure. The electronic device 1a may include a package, such as an electronic device package. In some arrangements, the electronic device 1a may include a carrier 10, an electronic component 11, a component 12, an underfill 13, and an encapsulant 14.

The carrier 10 may be configured to provide structural support for the electronic component 11, the component 12, the underfill 13, and the encapsulant 14. In some arrangements, the carrier 10 may be configured to reroute or redistribute the input/output (I/O) connections of the electronic component 11 and the component 12 to a different layout that is more suitable for packaging or interconnection with other components. For example, the carrier 10 may be configured to reroute or redistribute the I/O connections of the electronic component 11 and the component 12 to a board (not illustrated in the figures) through electrical contacts 10e.

In some arrangements, the line spacing of the I/O connections of the electronic component 11 may be smaller or finer than that of the carrier 10. For example, the value range of the Line/Space (L/S) ratio of the I/O connections of the electronic component 11 may be smaller than that of the carrier 10. In some arrangements, the line spacing of the I/O connections of the component 12 may be smaller or finer than that of the carrier 10. For example, the value range of the L/S ratio of the I/O connections of the component 12 may be smaller than that of the carrier 10. In some arrangements, the line spacing of the I/O connections of the electronic component 11 may be different from that of the component 12.

The carrier 10 may include one or more redistribution layers (RDLs). For example, the carrier 10 may include one or more conductive layers and one or more dielectric layers. A portion of the conductive layer may be covered or encapsulated by the dielectric layer, while another portion of the conductive layer may be exposed from the dielectric layer to provide electrical connections. The conductive layer may include a conductive material such as a metal or metal alloy. Examples of the conductive materials include gold (Au), silver (Ag), copper (Cu), platinum (Pt), palladium (Pd), other metals or alloys, or a combination of two or more of these. The dielectric layer may include a dielectric material, such as an epoxy-based material (e.g., epoxy resin with silica/alumina fillers), a molding compound (e.g., an epoxy molding compound or another type of molding compound), Ajinomoto build-up film (ABF), polyimide (PI), benzocyclobutene (BCB), silicon oxide, silicon nitride, etc. In some arrangements, the dielectric layer may include other suitable non-conductive materials or insulating materials. For example, the dielectric layer may include a nano-composite material composed of a dielectric material with a nano-filler material dispersed throughout. The transparency of the nano-composite material may range from about fifty percent to about ninety percent, and the nano-filler material may be shaped as a sheet, rod, core-shell, or tube.

The electronic component 11 may be disposed over the carrier 10. The electronic component 11 may be electrically connected to the carrier 10, and the electrical connections may be attained by way of solder bonding, Cu-to-Cu bonding, wire bonding, or hybrid bonding. For example, the electronic component 11 may be electrically connected with the conductive layer of the carrier 10 through electrical contacts 11e. In some arrangements, the electronic component 11 may be electrically connected to the carrier 10 by a metal-to-metal bonding, without a separate bonding material.

The electronic component 11 may include a surface 111 facing the carrier 10, a surface 112 opposite to the surface 111, and a surface 113 extending between the surface 111 and the surface 112. The surface 111 may be an active surface, a front surface, or a front side. The surface 112 may be a backside surface or a backside. The surface 113 may be a lateral surface or a sidewall.

In some arrangements, the electronic component 11 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 11 may include a radio frequency integrated circuit (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC. For example, the electronic component 11 may include a system on chip (SoC), a system-on-module (SoM), a system-in-package (SiP), or another type of IC that combines multiple components. Additionally, there may be any number of electronic components depending on design requirements.

The component 12 may be disposed over the carrier 10. The component 12 may be adjacent to the electronic component 11. The component 12 may be in the vicinity of the electronic component 11. In some arrangements, the distance (such as the shortest distance) between the component 12 and the electronic component 11 may be less than about 300 micrometers (μm). For example, the distance may be about 200 μm to 300 μm.

The component 12 may be electrically connected to the carrier 10, and the electrical connections may be attained by way of solder bonding, Cu-to-Cu bonding, wire bonding, or hybrid bonding. For example, the component 12 may be electrically connected with the conductive layer of the carrier 10 through electrical contacts 12e. In some arrangements, the component 12 may be electrically connected to the carrier 10 by a metal-to-metal bonding, without a separate bonding material.

In some arrangements, the electrical contacts 10e, 11e, and 12e may include solder balls or solder bumps, such as controlled collapse chip connection (C4) bumps, a ball grid array (BGA) or a land grid array (LGA).

The component 12 may include a surface 121 facing the carrier 10, a surface 122 opposite to the surface 121, and a surface 123 extending between the surface 121 and the surface 122. The surface 121 may be an active surface, a front surface, or a front side. The surface 122 may be a backside surface or a backside. The surface 123 may be a lateral surface or a sidewall. The surface 123 of the component 12 may face toward the surface 113 of the electronic component 11.

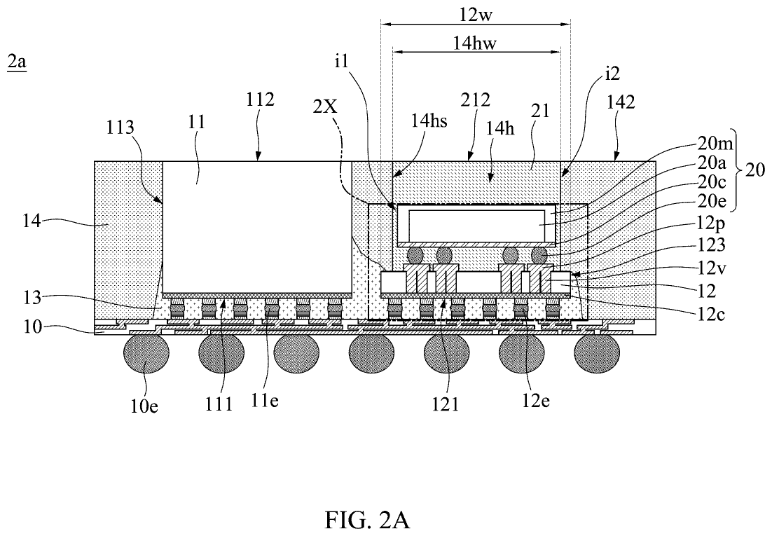

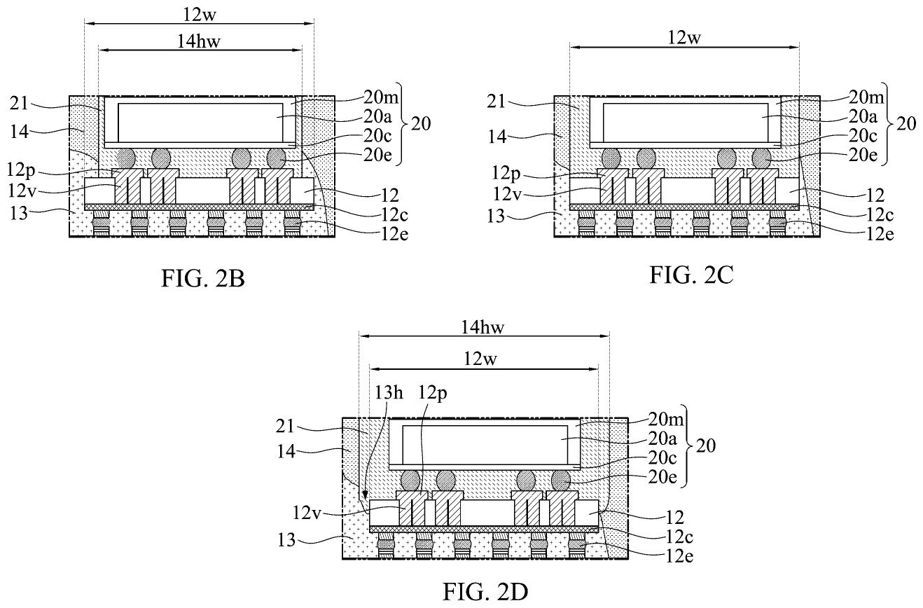

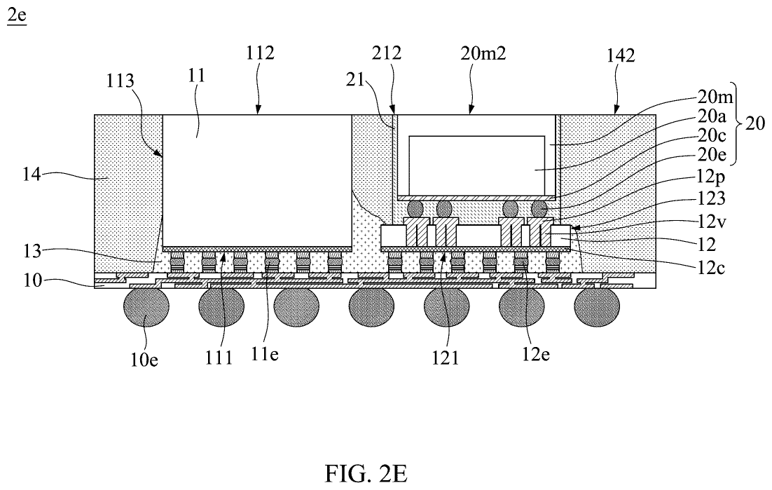

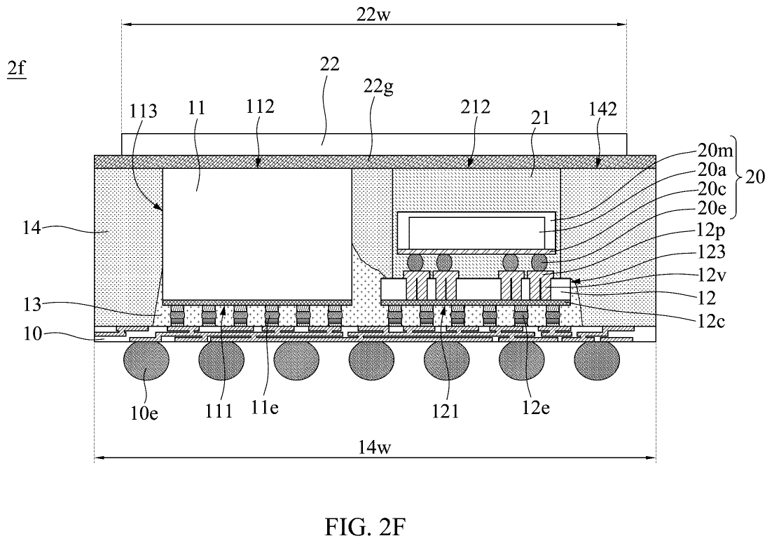

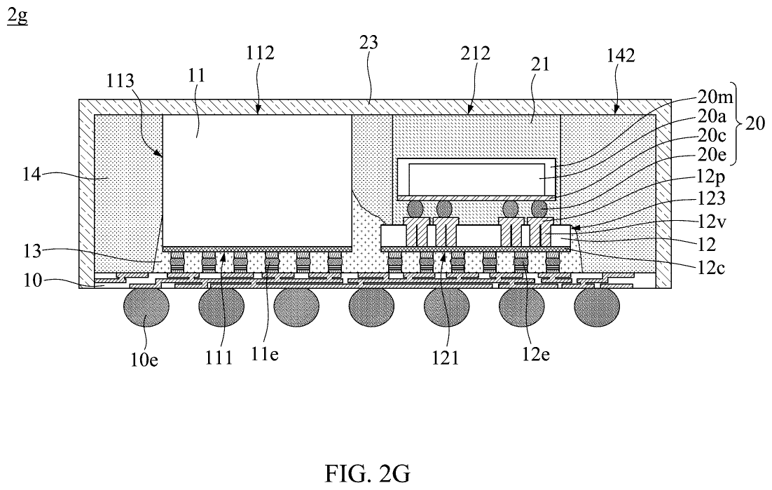

In some arrangements, the component 12 may be configured to predefine the location for placing another component (such as the package 20 in FIG. 2A). For example, the component 12 may be configured to serve as a predefined location or mounting point for the package 20. This arrangement helps to reduce manufacturing costs and improve overall yield by designating an RDL area for die placement. Additionally, it allows the placement of package 20 to be postponed until after the molding operation is complete. By deferring this step, the process minimizes potential damage to the package 20 during molding and enhances the precision of die alignment, ultimately contributing to higher product reliability and efficiency.

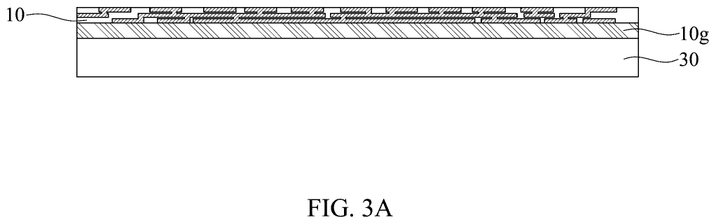

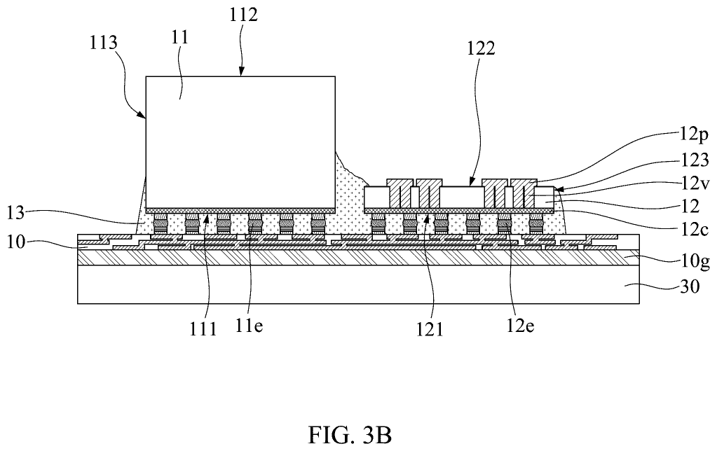

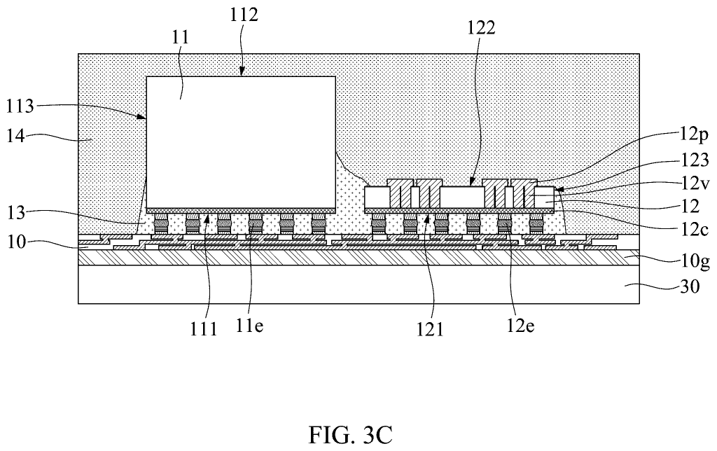

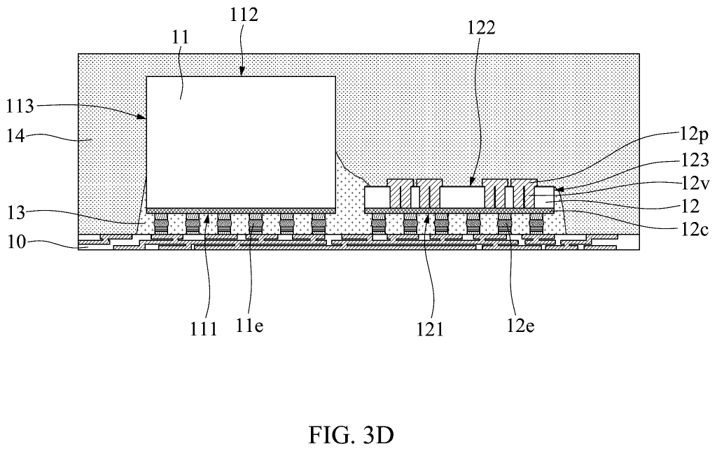

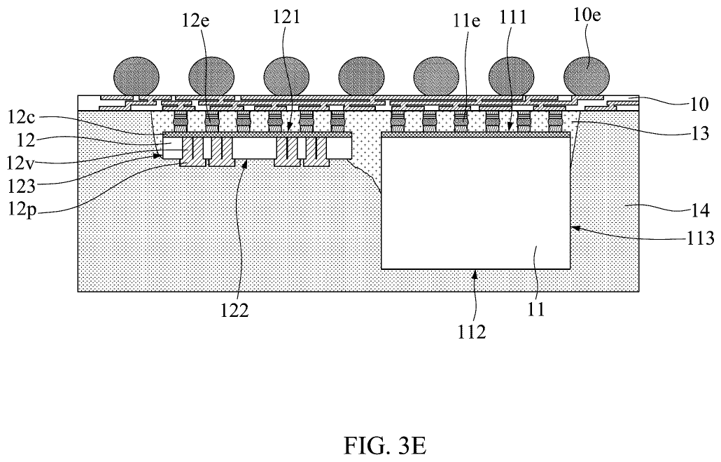

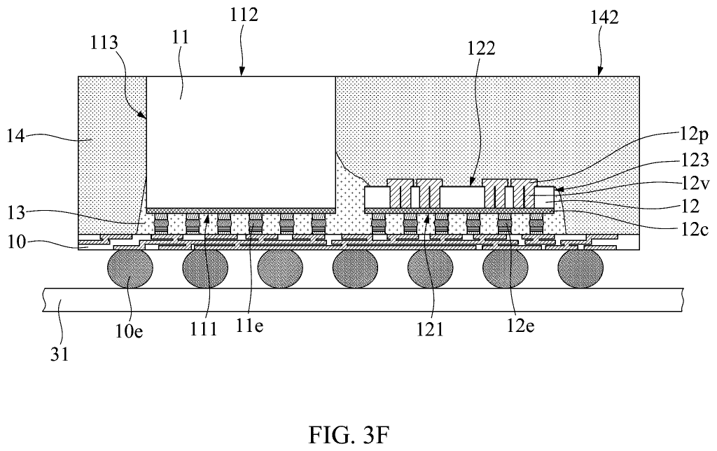

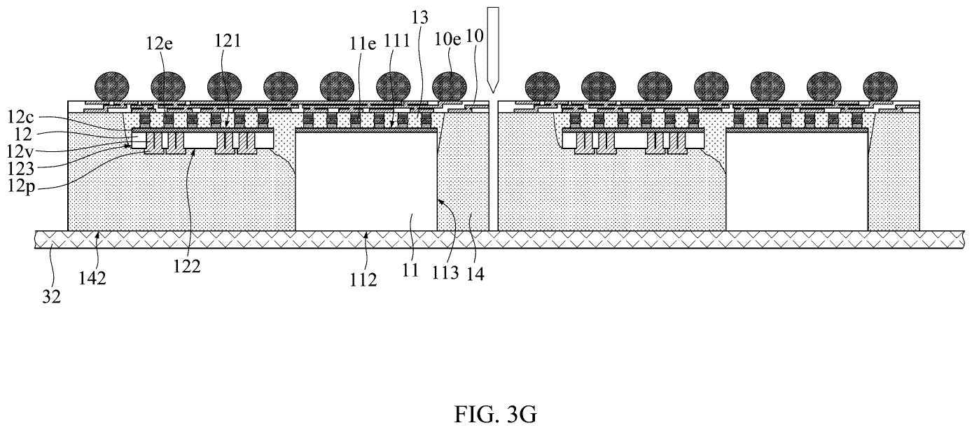

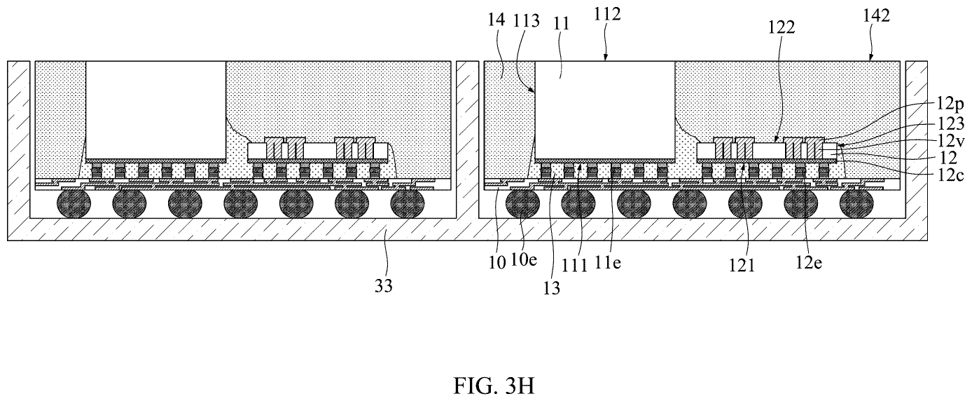

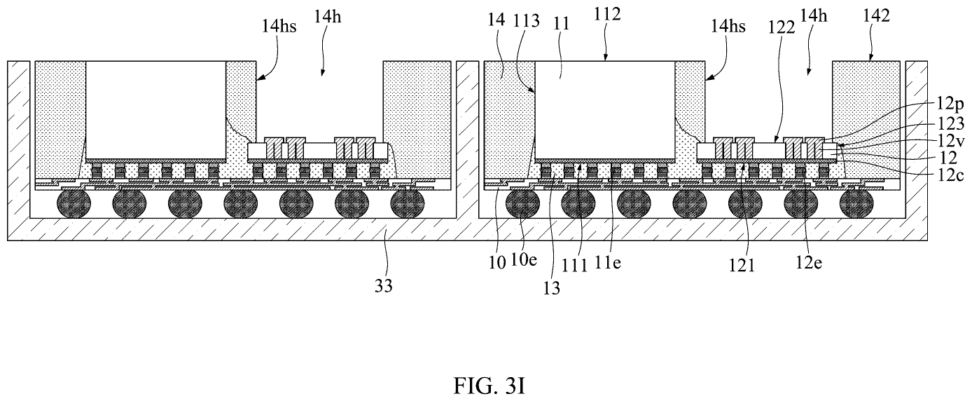

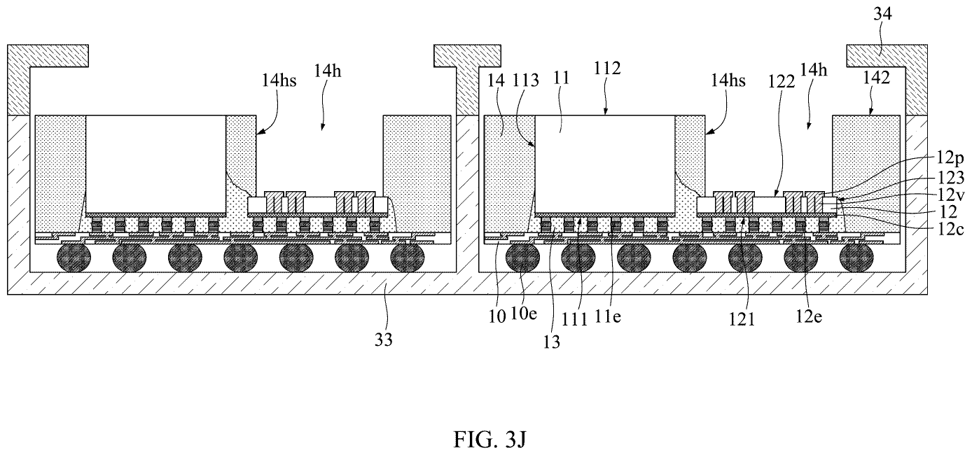

In some arrangements, the component 12 may be configured to protect the carrier 10 from damage or destruction during the formation of an opening 14h over the component 12. For example, as illustrated in the operation shown in FIG. 3I, the opening 14h may be created using methods such as laser cutting or chemical etching, and the component 12 may serve as a protective barrier, shielding the carrier 10 from the potentially harmful effects of the laser beam or the chemical etchant. This protective function helps to maintain the structural integrity of the carrier 10, ensuring that it remains intact and functional throughout the manufacturing process.

In some arrangements, the component 12 may include a logic die or an active component. In some arrangements, the component 12 may include control logic for managing memory operations. For example, the component 12 may be configured to communicate with a controller (such as the electronic component 11), receive commands, addresses, and data, and relay these commands, addresses, and data to another component (such as the package 20 in FIG. 2A).

For example, the component 12 may control or process the electrical signals actively. For example, the component 12 may perform functions such as amplifying, modulating, filtering, rectifying, switching, and/or converting the electrical signals that are either transmitted to or from the package 20. Specifically, the data transmitted to or from the package 20 may first undergo initial processing by the component 12. Subsequently, the processed data can be further handled or analyzed by the electronic component 11. The electronic component 11 may be a slave in a master-slave configuration with the component 12, wherein the component 12 provides control signals to the electronic component 11 through the carrier 10.

Alternatively, the data may first undergo initial processing by the electronic component 11, and then by the component 12. This layered approach to signal processing enhances the overall system performance by ensuring that signals are optimized before reaching their final destination within the electronic architecture.

In some arrangements, the component 12 may include an interposer, a bridge, an electrical interface, or a passive component. For example, the component 12 may be a silicon interposer, a glass interposer, a ceramic interposer, or another suitable interposer. For example, the component 12 may focus on providing robust and reliable location-based or protective functionalities without the complexities introduced by active circuitry. For example, the component 12 may exclude active devices such as transistors, diodes, ICs, operational amplifiers (op-amps), and similar devices.

The component 12 may include bridge metal coupling the package 20 to the carrier 10. The component 12 may include one or more conductive pads 12p disposed over the surface 122. The conductive pads 12p may be exposed on the surface 122. The conductive pads 12p may be configured to provide electrical connections for another component (such as the package 20 in FIG. 2A).

The component 12 may include one or more conductive vias 12v penetrating through the component 12 and electrically connected with the conductive pads 12p. The conductive vias 12v may be configured to provide vertical electrical connections between the carrier 10 and another component (such as the package 20 in FIG. 2A). The conductive vias 12v may be through-silicon vias (TSVs). In some arrangements, the component 12 may include one or more shielding lines disposed between adjacent ones of the conductive vias 12v. The shielding lines may be configured to provide electrostatic discharge (ESD) protection and to reduce electrical noise and interference.

In some arrangements, a circuit layer 12c may be disposed over the surface 121 of the component 12, and electrically connected with the conductive vias 12v and the conductive pads 12p. In some arrangements, the circuit layer 12c may include the active devices mentioned above. In some arrangements, the component 12 and the circuit layer 12c may form a reconfigurable interposer that has desired circuit functions complementary to another component (such as the package 20 in FIG. 2A). In some other arrangements, the circuit layer 12c may be omitted. For example, there may be no active devices between the carrier 10 and the component 12.

In some arrangements that include the circuit layer 12c, the line spacing of the I/O connections of the circuit layer 12c may be smaller or finer than that of the component 12. For example, the line spacing of the I/O connections of the circuit layer 12c may be the smallest or the finest in the electronic device 1a.

The underfill 13 may be disposed between the carrier 10 and the electronic component 11. The underfill 13 may surround or cover the electrical contacts 11e. The underfill 13 may climb onto the surface 113 of the electronic component 11. The climbing height (or the vertical coverage height, or the extension length) of the underfill 13 may vary. For example, the climbing height of the underfill 13 on the left side of the electronic component 11 may be less than that on the right side.

In some arrangements, the climbing height of the underfill 13 on the surface 113 of the electronic component 11 may be higher than the surface 122 of the component 12 with respect to the carrier 10. For example, the height to which the underfill 13 climbs along the surface 113 of the electronic component 11 may exceed the height of the surface 122 of the component 12 relative to the carrier 10. Such an arrangement can improve the reliability of the component 12 under thermal and mechanical loads.

The underfill 13 may be disposed between the carrier 10 and the component 12. The underfill 13 may surround or cover the electrical contacts 12e. The underfill 13 may climb onto the surface 123 of the component 12. The climbing height (or the vertical coverage height, or the extension length) of the underfill 13 may vary. For example, the climbing height of the underfill 13 on the left side of the component 12 may be greater than that on the right side. In some arrangements, the surface 123 of the component 12 may be entirely covered by the underfill 13. For example, the left side and the right side of the component 12 may be entirely covered by the underfill 13.

The underfill 13 may be disposed between the surface 123 of the component 12 and the surface 113 of the electronic component 11. The underfill 13 may be overlapped with the surface 123 of the component 12 and the surface 113 of the electronic component 11 along a direction substantially perpendicular to the surface 123 and/or the surface 113.

In some arrangements, the portion of the underfill 13 between the surface 123 of the component 12 and the surface 113 of the electronic component 11 may have a non-planar top surface or topology. For example, instead of being flat or level, the surface of the underfill 13 between the surface 123 of the component 12 and the surface 113 of the electronic component 11 may have varying elevations, contours, or other complex geometric features.

In some arrangements, the portion of the underfill 13 between the surface 123 of component 12 and the surface 113 of electronic component 11 may have a local roughness greater than 1, such as about 2, 3, 4, 5, 6, 7, 8, 9, 10, and so on. The local roughness may be calculated by dividing the arithmetic average roughness (Ra) by the mean spacing (Sm). Ra is the arithmetic average of the absolute values of roughness amplitude, and Sm is the mean spacing between peaks of the roughness. In some arrangements, the portion of the underfill 13 between the surface 123 of component 12 and the surface 113 of electronic component 11 may have a stepped configuration.

The underfill 13 may be liquid at room temperature and may have a relatively low viscosity for easy flow and filling of spaces or voids. In some arrangements, the underfill 13 may include an epoxy-based underfill, a silicone-based underfill, or a polyimide-based underfill. The underfill 13 may be chosen based on functions such as reducing mechanical stress, improving thermal cycling performance, and protecting solder joints. For example, the underfill 13 may be designed to have a low modulus, low coefficient of thermal expansion (CTE), and to generate low stress during temperature cycling.

In some arrangements, an underfill flow prevention feature may be disposed around the underfill 13. The underfill flow prevention feature may include a plurality of raised features disposed around the mounting region of the electronic component 11 and the component 12.

The encapsulant 14 may be disposed over the carrier 10. The encapsulant 14 may cover the electronic component 11, the component 12, and the underfill 13. The encapsulant 14 may have a surface (such as a top surface) 142. The encapsulant 14 and the underfill 13 may contact the surface 122 of the component 12. The surface 112 of the electronic component 11 may be at least partially exposed from the encapsulant 14. The surface 112 of the electronic component 11 and the surface 142 of the encapsulant 14 may be substantially coplanar or aligned.

The encapsulant 14 may define or have an opening 14h. The surface 122 of the component 12 may be partially exposed from the opening 14h and partially covered by the encapsulant 14. For example, the width 14hw of the opening 14h may be less than the width 12w of the component 12. For example, the periphery of the surface 122 of the component 12 may be covered by the encapsulant 14. The central portion of the surface 122 of the component 12 may be exposed from the opening 14h. The conductive pads 12p of the component 12 may be exposed from the opening 14h.

In some arrangements, the opening 14h may include a sidewall 14hs. The sidewall 14hs may be inside the edge or the boundary of the component 12. The sidewall 14hs may be inclined. The sidewall 14hs may be angled or oriented with respect to the surface 122 of the component 12. For example, a tapering angle of the opening 14 h may be greater than 90 degrees. In some arrangements, the sidewall 14hs may be a vertical surface or a surface substantially vertical to the surface 122 of the component 12. In some arrangements, the surface 113 of the electronic component 11 and the sidewall 14hs may have a general trend substantially perpendicular to the carrier 10.

In some arrangements, the opening 14h may be created using a laser-based process, and the laser technique may cause thermal effects on the adjacent sidewalls, potentially affecting the material properties in those areas. For example, the sidewall 14hs may become burnt or scorched as a result of the laser exposure. The underfill 13 may not be exposed from the sidewall 14hs.

In some arrangements, the encapsulant 14 may include an epoxy resin with fillers, a molding compound (e.g., an epoxy molding compound or another type of molding compound), a polyimide, a phenolic compound or material, a material with a silicone dispersed therein, or a combination thereof. In some arrangements, the encapsulant 14 may include a material different from that of the underfill 13.

For example, the encapsulant 14 may include a first Young's modulus, and the underfill 13 may include a second Young's modulus. A Young's modulus ratio (i.e., the ratio of the second Young's modulus to the first Young's modulus) may be greater than 1. For example, the flowability of the encapsulant 14 may be less than the flowability of the underfill 13.

FIG. 1B illustrates a partial enlarged view of an electronic device in accordance with some arrangements of the present disclosure. For example, the electronic device 1a may have the structure shown in FIG. 1B. In some arrangements, the structure in FIG. 1B is similar to the structure in the dotted box X in FIG. 1A, except that the underfill 13 is exposed from the opening 14h. The underfill 13 is exposed from the sidewall 14hs of the opening 14h. For example, the underfill 13 and the encapsulant 14 may together define the sidewall 14hs of the opening 14h.

In some arrangements, the underfill 13 may climb onto the surface 122 of the component 12, and the underfill 13 on the surface 122 may be partially removed during the formation of the opening 14h, resulting in a cutting surface or an exposed surface of the underfill 13. In some arrangements, the cutting surface of the underfill 13 and the cutting surface of the encapsulant 14 may be substantially coplanar or aligned. In some arrangements, the cutting surface of the underfill 13 and the cutting surface of the encapsulant 14 may become burnt or scorched as a result of the laser exposure. In some arrangements, the encapsulant 14 may be spaced apart from the surface 122 of the component 12 by the underfill 13. For example, the encapsulant 14 may not contact the surface 122 of the component 12. In some arrangements, the encapsulant 14 and the underfill 13 may be overlapped with the surface 122 of the component 12 in a direction substantially vertical to the surface 122 of the component 12. In some arrangements, an interface between the encapsulant 14 and the underfill 13 may be higher than the component 12 with respect to the carrier 10.

FIG. 1C illustrates a partial enlarged view of an electronic device in accordance with some arrangements of the present disclosure. For example, the electronic device 1a may have the structure shown in FIG. 1C. In some arrangements, the structure in FIG. 1C is similar to the structure in the dotted box X in FIG. 1A except that the width of the opening 14h may be substantially equal to the width 12w of the component 12. The sidewall 14hs of the opening 14h be substantially aligned with the surface 123 of the component 12.

FIG. 1D illustrates a partial enlarged view of an electronic device in accordance with some arrangements of the present disclosure. For example, the electronic device 1a may have the structure shown in FIG. 1D. In some arrangements, the structure in FIG. 1D is similar to the structure in the dotted box X in FIG. 1A, except that the width 14hw of the opening 14h may be greater than the width 12w of the component 12. The surface 123 of the component 12 may be partially exposed from the opening 14h. For example, an upper portion of the surface 123 of the component 12 may be exposed from the opening 14h.

In some arrangements, the underfill 13 may have a recessed portion 13h adjacent to the surface 123 of the component 12. The recessed portion 13h may be a cavity, a gap, or a concave region. The surface 123 of the component 12 may be partially exposed from the recessed portion 13h. In some arrangements, the lowest point of the recessed portion 13h may be spaced apart from the surface 123 of the component 12. In some arrangements, the lowest point of the recessed portion 13h may be located between the surface 121 and the surface 122 of the component 12. In some arrangements, an interface between the encapsulant 14 and the underfill 13 may be lower than the surface 122 of the component 12 with respect to the carrier 10.

In some arrangements, the surface (such as the bottom surface or the sidewall) of the recessed portion 13h may be uneven. In some arrangements, the underfill 13 and the component 12 may together protect the carrier 10 from damage or destruction during the formation of an opening 14h over the component 12. For example, the parameters of the laser beam or the concentration and application of the chemical etchant can be carefully adjusted so that the area of the carrier 10 covered exclusively by the underfill 13 remains adequately shielded. For example, the component 12 may protect the carrier 10 through collaborative operation with the underfill 13.

FIG. 2A illustrates a cross-sectional view of an electronic device 2a in accordance with some arrangements of the present disclosure. The electronic device 2a is similar to the electronic device 1a in FIG. 1A, except that the electronic device 2a further includes the package 20 and the encapsulant 21.

The package 20 may be disposed over the component 12. The package 20 may be disposed in the opening 14h. The package 20 may be surrounded by the encapsulant 14. The package 20 and the component 12 may be substantially overlapped in the direction substantially perpendicular to the surface 122 of the component 12.

The package 20 may be electrically connected to the component 12, and the electrical connections may be attained by way of solder bonding, Cu-to-Cu bonding, wire bonding, or hybrid bonding. For example, the package 20 may be electrically connected with the component 12 through electrical contacts 20e.

The package 20 may include a memory package, such as a dynamic random access memory (DRAM) package, a static RAM (SRAM) package, a read-only memory (ROM) package, a flash memory package, a magnetoresistive RAM (MRAM) package, etc. However, the inventive concept is not limited thereto. For example, the package 20 may be or include other types of packages, such as a transceiver package, a processing package, a networking package, a voltage regulating package (which may provide a regulated voltage), etc.

In some arrangements, the package 20 may include a carrier 20c, a component 20a, and an encapsulant 20m. The carrier 20c may be configured to provide structural support for the component 20a and the encapsulant 20m. The component 20 a may include one or more memory dies. For example, FIG. 2A may illustrate only the outermost memory die, providing a focused view of its structure and layout without depicting the underlying or adjacent dies. In some arrangements, the component 20 a may include other types of dies. The encapsulant 20m may be disposed over the carrier 20c and covering the component 20a.

The encapsulant 20m may include a material as listed above with respect to the encapsulant 14. In some arrangements, the encapsulant 20m may include a material different from that of the encapsulant 14. In some arrangements, the encapsulant 20m and the encapsulant 14 may include the same material having a distinguishable interface therebetween.

The encapsulant 21 may fill the gap or space within the opening 14h after the package 20 has been placed inside the opening 14h. The encapsulant 21 may form a sealed space between the package 20 and the encapsulant 14. The encapsulant 21 may cover the package 20. The central portion of the surface 122 of the component 12 may be covered by the encapsulant 21. The peripheral portion of the surface 122 of the component 12 may be covered by the underfill 13 and/or the encapsulant 14. This filling process helps to ensure a secure fit, providing structural support and protection for the package 20, while also preventing the ingress of contaminants such as dust or moisture.

The encapsulant 21 may include a material as listed above with respect to the encapsulant 14. In some arrangements, the encapsulant 21 may include a material different from that of the encapsulant 14. In some arrangements, the encapsulant 21 and the encapsulant 14 may include the same material having a distinguishable interface therebetween.

The encapsulant 21 may cover, surround, or encapsulate the encapsulant 20m. In some arrangements, the encapsulant 21 and the encapsulant 20m may define or include an interface or a boundary i1. For example, the interface i1 may be present at the junction where the encapsulant 21 meets the encapsulant 20m. For example, the interface i1 may be a void-free interface.

The encapsulant 14 may cover, surround, or encapsulate the encapsulant 21. In some arrangements, the encapsulants 14 and 21 may define or include an interface or a boundary i2. For example, the interface i2 may be present at the junction where the encapsulant 14 meets the encapsulant 21. For example, the interface i2 may be a void-free interface.

The encapsulant 21 may have a surface (such as a top surface) 212. The surface 112 of the electronic component 11, the surface 142 of the encapsulant 14, and the surface 212 of the encapsulant 21 may be substantially coplanar or aligned.

FIG. 2B illustrates a partial enlarged view of an electronic device in accordance with some arrangements of the present disclosure. For example, the electronic device 2a may have the structure shown in FIG. 2B. In some arrangements, the structure in FIG. 2B is similar to the structure in the dotted box 2X in FIG. 2A, except that the underfill 13 contacts the encapsulant 21. For example, the underfill 13 and the encapsulant 14 may define a coplanar surface contacting the encapsulant 21. In some arrangements, an interface between the encapsulant 21 and the underfill 13 may be within a boundary of the component 12.

FIG. 2C illustrates a partial enlarged view of an electronic device in accordance with some arrangements of the present disclosure. For example, the electronic device 2a may have the structure shown in FIG. 2C. In some arrangements, the structure in FIG. 2C is similar to the structure in the dotted box 2X in FIG. 2A, except that the width of the opening 14h may be substantially equal to the width 12w of the component 12. For example, the underfill 13 and the encapsulant 14 may define a coplanar surface substantially aligned with the surface 123 of the component 12.

FIG. 2D illustrates a partial enlarged view of an electronic device in accordance with some arrangements of the present disclosure. For example, the electronic device 2a may have the structure shown in FIG. 2D. In some arrangements, the structure in FIG. 2D is similar to the structure in the dotted box 2X in FIG. 2A, except that the width 14hw of the opening 14h may be greater than the width 12w of the component 12.

The surface 123 of the component 12 may be partially covered by the encapsulant 21 and partially covered by the underfill 13. For example, the upper surface of the surface 123 of the component 12 may be covered by the encapsulant 21, and the lower surface of the surface 123 of the component 12 may be covered by the underfill 13. In some arrangements, an interface between the encapsulant 21 and the underfill 13 may be outside a boundary of the component 12.

FIG. 2E illustrates a cross-sectional view of an electronic device 2e in accordance with some arrangements of the present disclosure. The electronic device 2e is similar to the electronic device 2a in FIG. 2A except that in the electronic device 2 e, the encapsulant 20m may have a surface (such as a top surface) 20m2. The surface 20m2 of the encapsulant 20m may be at least partially exposed from the encapsulant 21. The surface 112 of the electronic component 11, the surface 142 of the encapsulant 14, the surface 212 of the encapsulant 21, and the surface 20m2 of the encapsulant 20m may be substantially coplanar or aligned.

FIG. 2F illustrates a cross-sectional view of an electronic device 2f in accordance with some arrangements of the present disclosure. The electronic device 2f is similar to the electronic device 2a in FIG. 2A, except that the electronic device 2f further includes a heat dissipating element 22 connecting thereto through an adhesive layer 22g, such as a heat dissipating gel. The heat dissipating element 22 may include a heat transfer unit and may have a relatively high thermal conductivity. For example, the heat dissipating element 22 may include copper (Cu), aluminum (Al), graphite, ceramics, etc. The heat dissipating element 22 may include a block, a pipe, a sink, a fin, or other shapes.

In some arrangements, a width 22w of the heat dissipating element 22 may be less than a width 14w of the encapsulant 14. For example, a portion of the adhesive layer 22g may be uncovered by the heat dissipating element 22.

FIG. 2G illustrates a cross-sectional view of an electronic device 2g in accordance with some arrangements of the present disclosure. The electronic device 2g is similar to the electronic device 2a in FIG. 2A, except that the electronic device 2g further includes a shielding layer 23.

The shielding layer 23 may include a substantially conformal layer or conformal shield. For example, the shielding layer 23 may be conformal to the encapsulant 14. The shielding layer 23 may be formed by a plating process. The shielding layer 23 may be disposed on the surface 112 of the electronic component 11, the surface 142 of the encapsulant 14, the surface 212 of the encapsulant 21, and a lateral surface of the carrier 10.

The shielding layer 23 may be electrically connected to a grounding element of the carrier 10. In some arrangements, the shielding layer 23 may include a conductive thin film composed of materials such as copper, aluminum, or conductive polymers, which facilitate effective electrical conductivity. Additionally, the shielding layer 23 may be designed to provide ESD protection, thereby safeguarding sensitive components within the electronic device 2g from potential damage caused by sudden electrical surges or static electricity.

FIGS. 3A, 3B, 3C, 3D, 3E, 3F, 3G, 3H, 3I, and 3J are cross-sections of one or more stages of a method of manufacturing an electronic device in accordance with some arrangements of the present disclosure. At least some of these figures have been simplified to better understand the aspects of the present disclosure. In some arrangements, the electronic device 1a may be manufactured through the steps illustrated in FIGS. 3A, 3B, 3C, 3D, 3E, 3F, 3G, 3H, 3I, and 3J.

Referring to FIG. 3A, a temporary carrier 30 may be provided (e.g., manufactured or obtained). The temporary carrier 30 may be a glass carrier, a metal carrier, a ceramic carrier, or other suitable carriers. The temporary carrier 30 may include a panel, and the size thereof can be approximately 300 mm square, 500 mm square, 600 mm square, or larger. For example, the electronic device 1a may be implemented using a panel level packaging (PLP) process. In the PLP process, a panel is used to fabricate multiple semiconductor packages simultaneously. Compared to conventional wafer-level packaging (WLP), the use of a panel allows for greater production throughput and improved material utilization, as a result of the increased substrate size. The rectangular substrate is typically formed of an organic laminate material or a glass-based substrate, and may include pre-defined cutting streets (saw lanes) along rows and columns to facilitate singulation after encapsulation and other back-end processes.

The carrier 10 may be formed over the temporary carrier 30. The carrier 10 may be attached to the temporary carrier 30 through an adhesive layer 10g. The adhesive layer 10g may include a die attach film (DAF), a glue, a bonding layer, an underfill, or another suitable material.

In some arrangements, due to the rectangular geometry of the panel, electroplating during RDL formation may result in charge accumulation at the corners, leading to unique microstructural effects on the routing lines near the panel edges—effects that do not occur on circular wafers. To compensate for plating non-uniformity at the panel corners, dummy structures may be densely distributed in these regions. Furthermore, the panel's cutting streets are typically aligned parallel or perpendicular to the panel edges, which is structurally distinct from the dicing paths on wafers.

Referring to FIG. 3B, the electronic component 11 and the component 12 may be disposed over the temporary carrier 30.

In some arrangements, more than two electronic devices may be placed on the temporary carrier 30 in a batch and subjected to similar or identical processes in the manufacturing method. For example, the electronic components 11 may be arranged in an N×M array. For example, the components 12 may be arranged in an N×M array. For example, the sidewalls of the electronic components 11 may be aligned with the sidewalls of the components 12 forming a symmetric array. For example, the relative displacements between the sidewalls of the electronic components 11 and the sidewalls of the components 12 may be substantially equal.

In some arrangements, compared to WLP, PLP is based on a rectangular panel substrate on which multiple components are arranged in an N×M array, with each row and each column containing the same number of components. This uniform grid arrangement is a characteristic feature of PLP and differs from WLP, where die density is typically higher at the wafer center and lower at the periphery. For example, WLP includes a central region including a relatively higher density of dies and a peripheral region including a relatively lower density of dies. In PLP, the outermost row and the outermost column may share a single component located at the panel corner—a layout that is uncommon on a circular wafer.

The underfill 13 may be disposed over the temporary carrier 30. The underfill 13 may connect the electronic component 11 and the component 12 to the temporary carrier 30. For example, the electronic component 11 and the electronic component 12 may be positioned at specific locations on a support structure within a dispensing system during the application of the underfill material 13. In certain configurations, an image of the underfill 13 can be captured in situ, that is, directly during the dispensing process. This real-time imaging allows for precise monitoring of the underfill application. Using the captured image, the fillet width of the underfill can be accurately measured. Based on these measurements, a plurality of threshold levels for the fillet width can be established, which may be used to ensure quality control and consistency in the dispensing process.

In some arrangements, the underfill 13 may be formed through anisotropic deposition techniques. Unlike isotropic deposition, in which material is deposited uniformly in all directions, anisotropic deposition produces a non-uniform film or structure by selectively enhancing deposition in targeted areas.

Referring to FIG. 3C, the encapsulant 14 may be disposed over the carrier 10 to cover the electronic component 11, the component 12, and the underfill 13. In some arrangements, the encapsulant 14 may be formed by a molding technique, such as transfer molding, injection molding, or compression molding.

Referring to FIG. 3D, the temporary carrier 30 and the adhesive layer 10g may be removed, and the carrier 10 may be exposed.

Referring to FIG. 3E, the electrical contact 10e may be formed over the carrier 10.

Referring to FIG. 3F, the structure obtained from the operation of FIG. 3E may be disposed over a temporary carrier 31. A planarization operation or a grinding operation may be performed to remove a portion of the encapsulant 14 to expose the surface 112 of the electronic component 11. The planarization operation or grinding operation may include an abrasive machining process that uses a grinding wheel or grinder, a chemical mechanical planarization (CMP) process, an etching process, or a laser direct ablation (LDA) process.

Referring to FIG. 3G, the structure obtained from the operation of FIG. 3F may be disposed over a dicing tape 32. A singulation operation may be performed. The electronic device assembly may be singulated or separated into a plurality of individual units or segmented parts in a singulation operation. In some arrangements, the singulation operation may be applied using a saw blade or laser cutting tool.

Referring to FIG. 3H, the individual units obtained from the operation of FIG. 3H may be disposed or sorted over a board 33. For example, the board 33 may include a plurality of holes or openings, and the individual units may be disposed in a corresponding opening.

Referring to FIG. 3I, the opening 14h may be formed by a laser direct ablation (LDA) process, a laser drilling process, a laser cutting process, or an etching process. The component 12 may be configured to protect the carrier 10 from damage or destruction during the formation of an opening 14h over the component 12.

Referring to FIG. 3J, before the product is packaged and shipped, a cover 34 may be placed over the board 33 to facilitate a thorough cleaning process. This cleaning process can include multiple steps such as washing the board with water to remove any contaminants or residues, followed by baking it in an oven to ensure complete drying and to eliminate any remaining moisture. In some arrangements, the product may be shipped to a different production line for the placement of the package 20. Compared to an embodiment that does not include the component 12, the presence of the component 12 can enhance the overall structural strength and durability of the product.

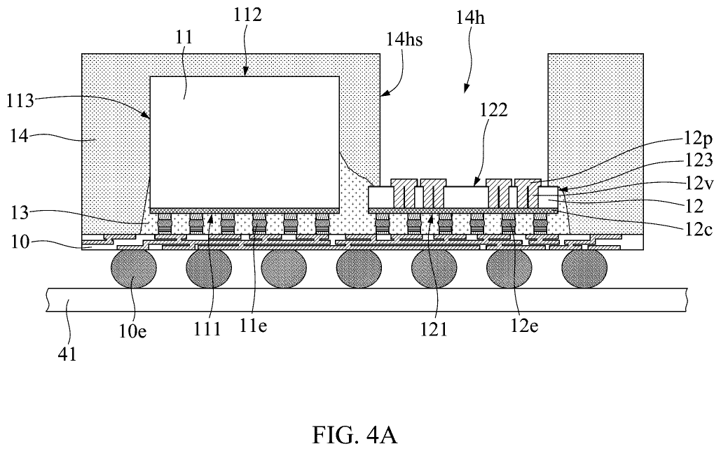

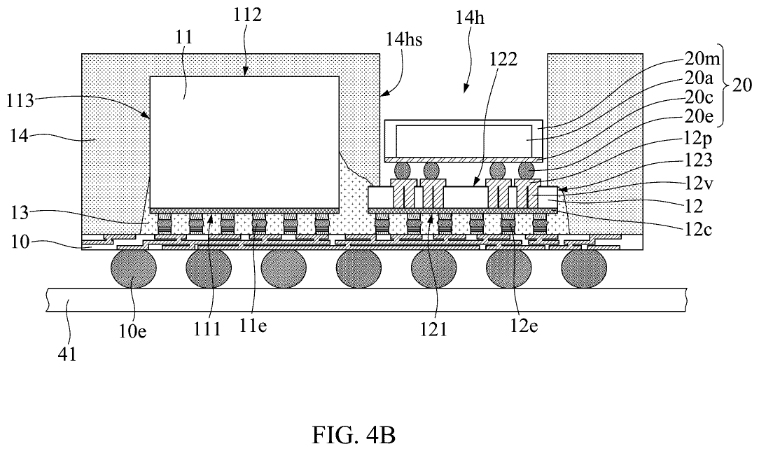

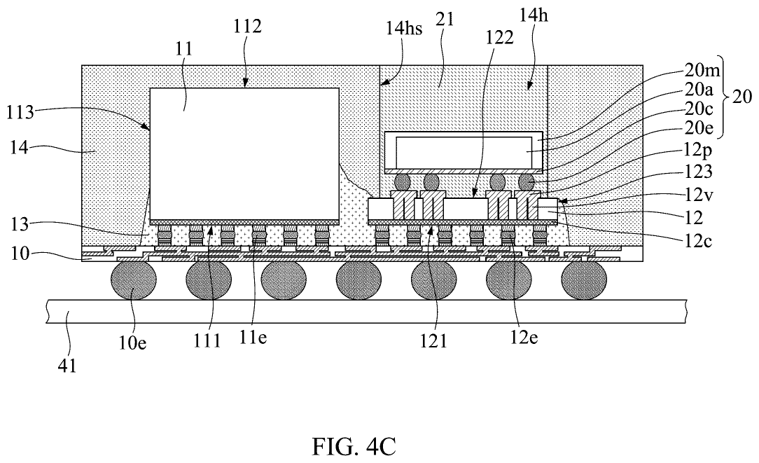

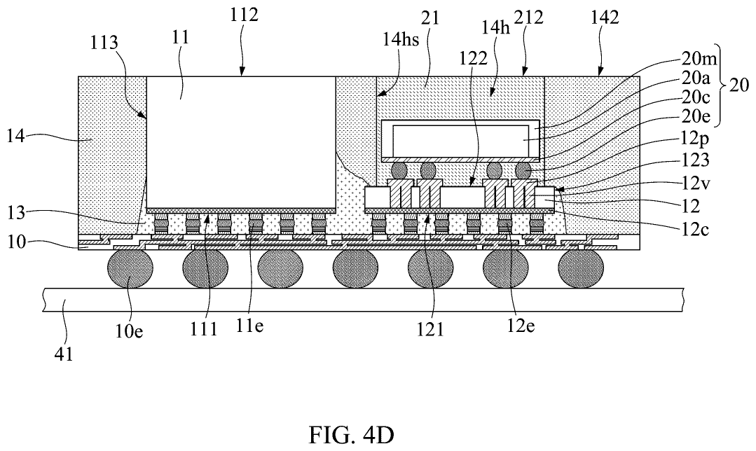

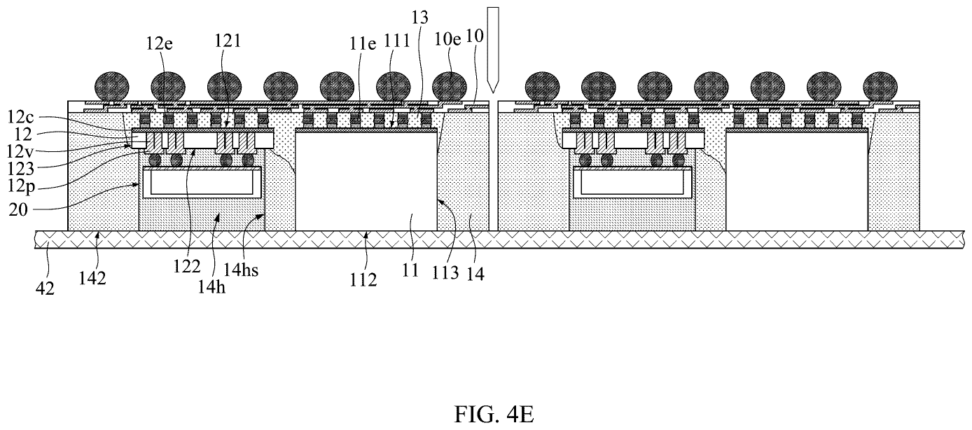

FIGS. 4A, 4B, 4C, 4D, and 4E are cross-sections of one or more stages of a method of manufacturing an electronic device in accordance with some arrangements of the present disclosure. At least some of these figures have been simplified to facilitate better understanding of the aspects of the present disclosure. In some arrangements, the electronic device 2a may be manufactured through the steps illustrated in FIGS. 4A, 4B, 4C, 4D, and 4E.

Referring to FIG. 4A, which is subsequent to the operation in FIG. 3E, the structure obtained from the operation of FIG. 3E may be disposed over a temporary carrier 41. The opening 14h may be formed by a laser direct ablation (LDA) process, a laser drilling process, a laser cutting process, or an etching process. The component 12 may be configured to protect the carrier 10 from damage or destruction during the formation of an opening 14h over the component 12.

Referring to FIG. 4B, the package 20 may be disposed over the component 12 and in the opening 14h. In some arrangements, an electrical test can be performed on the carrier 10 before mounting the package 20.

Conventionally, the package (such as a memory package) is molded together with the IC die within the encapsulant. During subsequent processing steps, the package is at risk of being damaged. This conventional approach introduces significant challenges, as any damage incurred cannot be rectified by removing or replacing the package after the molding process. Consequently, this conventional approach often results in higher manufacturing costs and lower production yields, as defective packages lead to increased waste and rework.

According to some arrangements of the present disclosure, the invention employs the component 12 placed on a designated RDL area for die placement, followed by molding and creating an opening to expose pads of the component 12. This allows electrical testing of the RDL before die attachment, thereby facilitating early defect detection, reducing costs, and improving yield.

In some arrangements, an electrical test may be conducted after the package 20 has been placed within the opening 14h. If either the package 20 or the carrier 10 is found to be defective during this test, the method includes disengaging and removing the package 20 from the opening to allow for replacement or further inspection.

In some arrangements, the package 20 or the carrier 10 are controlled to operate in a repair mode, wherein the testing signal is redirected away from the damaged pathway and routed through an alternative route instead.

Referring to FIG. 4C, the encapsulant 21 may fill the gap or space within the opening 14h after the package 20 has been placed inside the opening 14h. In some arrangements, the encapsulant 21 may be formed by a molding technique, such as transfer molding, injection molding, or compression molding.

Referring to FIG. 4D, a planarization operation or a grinding operation may be performed to remove portions of the encapsulants 14 and 21, exposing the surface 112 of the electronic component 11.

Referring to FIG. 4E, the structure obtained from the operation of FIG. 4D may be disposed over a dicing tape 42. A singulation operation may be performed. The electronic device assembly may be singulated or separated into a plurality of individual units in a singulation operation. In some arrangements, the singulation operation may be applied using a saw blade or laser cutting tool.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a redistribution layer (RDL);
a component disposed over the RDL;
an underfill disposed between the RDL and the component; and
an encapsulant covering the component,
wherein the encapsulant or the underfill defines a surface adjacent to a sidewall of the component and substantially vertical to the component.

2. The electronic device of claim 1, wherein the encapsulant or the underfill defines an opening having the surface and exposing a conductive pad of the component.

3. The electronic device of claim 2, wherein the opening is configured to accommodate a memory package.

4. The electronic device of claim 2, wherein the underfill is exposed from the opening.

5. The electronic device of claim 1, wherein the underfill defines a recessed portion adjacent to the sidewall of the component.

6. An electronic device, comprising:
a redistribution layer (RDL);
a chip disposed over the RDL;
a memory package disposed over the RDL and adjacent to the chip, wherein the memory package includes a first encapsulant; and
a second encapsulant covering the memory package,
wherein the first encapsulant and the second encapsulant have a first interface therebetween.

7. The electronic device of claim 6, further comprising:
a third encapsulant covering the chip and the second encapsulant, wherein the third encapsulant and the second encapsulant have a second interface therebetween.

8. The electronic device of claim 7, wherein a top surface of the third encapsulant is substantially aligned with a top surface of the first encapsulant.

9. The electronic device of claim 6, further comprising:
an interposer connecting between the memory package and the RDL.

10. The electronic device of claim 9, wherein a central portion of the interposer is covered by the second encapsulant.

11. The electronic device of claim 10, further comprising:
an underfill connecting between the interposer and the RDL.

12. The electronic device of claim 11, wherein a peripheral portion of the interposer is covered by the underfill.

13. An electronic device, comprising:
a redistribution layer (RDL);
an interposer disposed over the RDL;
an underfill disposed between the RDL and the interposer; and
a first encapsulant covering the underfill,
wherein the first encapsulant or the underfill defines an opening over the interposer for accommodating a memory package.

14. The electronic device of claim 13, wherein the interposer is configured to protect the RDL from damage during a formation of the opening.

15. The electronic device of claim 13, wherein an interface between the first encapsulant and the underfill is higher than the interposer with respect to the RDL.

16. The electronic device of claim 13, wherein with respect to the RDL, an interface between the first encapsulant and the underfill is lower than a surface of the interposer facing away from the RDL.

17. The electronic device of claim 13, wherein the interposer includes a circuit layer disposed on a surface of the interposer facing toward the RDL.

18. The electronic device of claim 17, wherein a line spacing of the circuit layer is smaller than a line spacing of the interposer.

19. The electronic device of claim 18, wherein the line spacing of the interposer is smaller than a line spacing of the RDL.

20. The electronic device of claim 13, further comprising:
a second encapsulant disposed in the opening and contacting the underfill.
